(19) United States
(12) Patent Application Publication
(10) Pub. No.: US 2016/0079400 A1
(43) Pub. Date: Mar. 17, 2016

(54) A JUNCTION-MODULATED TUNNELING FIELD EFFECT TRANSISTOR AND A FABRICATION METHOD THEREOF

(71) Applicant: PEKING UNIVERSITY, Beijing (CN)

(72) Inventors: Ru Huang, Beijing (CN); Qianqian Huang, Beijing (CN); Chunlei Wu, Beijing (CN); Jiaxin Wang, Beijing (CN); Zhan Zhan, Beijing (CN); Yangyuan Wang, Beijing (CN)

(21) Appl. No.: 14/787,262

(22) PCT Filed: Jan. 9, 2014
(86) PCT No.: PCT/CN2014/070352

§ 371 Date: Oct. 26, 2015

(30) Foreign Application Priority Data
Nov. 8, 2013 (CN) 201310552567.5

(51) Int. Cl. H01L 29/66; H01L 29/08; H01L 29/36; H01L 21/324; H01L 21/3065; H01L 21/308; H01L 21/266; H01L 29/78; H01L 29/10

(52) U.S. Cl. CPC H01L 29/66977; H01L 29/7827; H01L 29/66666; H01L 29/0847; H01L 29/36; H01L 29/1033; H01L 21/3065; H01L 21/3085; H01L 21/266; H01L 21/324

(57) ABSTRACT

The present invention discloses a junction-modulated tunneling field effect transistor and a fabrication method thereof, belonging to a field of field effect transistor logic device and the circuit in connection with CMOS ultra large scale integrated circuit (ULSI). The PN junction provided by a highly-doped source region surrounding three sides of the vertical channel region of the tunneling field effect transistor can deplete effectively the channel region, so that the energy band of the surface channel under the gate is lifted, therefore the device may obtain a steeper energy band and a narrower tunneling barrier width than the conventional TFET when the band-to-band tunneling occurs, equivalently achieving the effect of a steep doping concentration gradient at the source tunneling junction, and thereby the sub-threshold characteristics are significantly improved while the turn-on current of the device is improved relative to the conventional TFET. Under the conditions that the device of the present invention is compatible with the existing CMOS process, on the one hand an ambipolar effect of the device can be inhibited effectively, while a parasitic tunneling current at a source junction corner in the small size device can be inhibited and thus can equivalently achieve an effect of a steep doping concentration gradient at the source junction.

The present application claims priority of Chinese Patent Application (No. 201310552567.5) filed on Nov. 8, 2013, which is incorporated herein by reference in its entirety.

### TECHNICAL FIELD

The invention belongs to a field of a field effect transistor logic device and the circuit in connection with CMOS ultra large scale integrated circuit (ULSI), and particularly refers to a junction-modulated tunneling field effect transistor and a fabrication method thereof.

### BACKGROUND OF THE INVENTION

Under the drive of Moore's Law, the feature size of the conventional MOSFET continually shrink and now has progressed to the nanometer scale, consequently, the negative effects such as short channel effect of a device and so on have become increasingly critical. The effects such as drain induced barrier lowering and band-to-band tunneling cause a off-state leakage current of a device to increase continually, and at the same time, a sub-threshold slope of the conventional MOSFET can not decrease synchronously with the shrink of the device size due to the limitation by the thermal potential, and thereby result in increase of the device power consumption. Now the power consumption concern has become the most serious problem of limiting the device shrink.

In order to enable the device to be applied in the field of ultra-low voltage and low power consumption, Achievement of a device structure with ultra-steep sub-threshold slope based on a new turn-on mechanism and a process and fabrication method thereof have become the focus drawing everyone's attentions to small size devices. In recent years, researchers have proposed a possible solution of using tunneling field effect transistor (TFET). Not like the conventional MOSFET, TFET has source and drain with opposite doping types each other, can control the band-to-band tunneling of the reverse biased PIN junction by gate to achieve turn-on, can break through the limitation of the sub-threshold slope 60 mV/dec of the conventional MOSFET, and has a very small leakage current. TFET has many advantages such as low leakage current, low sub-threshold slope, low operating voltage and low power consumption. However, due to the limitation of source junction tunneling probability and tunneling area, TFET is faced with an issue of small on-state current, which is far less than the conventional MOSFET devices, and this greatly limits the applications of TFET device. In addition, it is difficult to achieve TFET device with a steep sub-threshold slope in the experiment, because it is more difficult to achieve a steep doping concentration gradient at the source junction in the experiment, so that the electric field at the tunneling junction when the device turns on is not sufficiently large, which may cause a sub-threshold slope of TFET to degrade relative to the theoretical value. Therefore, it has become a further important problem in connection with TFET device how to achieve a steep doping concentration gradient at the source junction so as to obtain an ultra-low sub-threshold slope.

### SUMMARY OF THE INVENTION

The purpose of the present invention is to provide a junction-modulated tunneling field effect transistor and a fabrication method thereof. While the device is fully compatible with the existing CMOS process, the device can equivalently achieve an effect of a steep source junction doping concentration gradient at a source junction, significantly optimize a sub-threshold slope of TFET device, and at the same time increase a turn-on current thereof. Furthermore, due to presence of a region between the gate and the drain and not covered with the gate, on the one hand an ambipolar effect of the device can be effectively inhibited, while a parasitic tunneling current at a source junction corner in the small size can be inhibited.

The technical solutions of the present invention are provided as follows.

A tunneling field effect transistor according to the present invention includes a semiconductor substrate (1), a vertical channel region (2), a highly-doped source region (4), a lowly-doped drain region (8), a gate dielectric layer (5), and a control gate (6), and a gate electrode (9) coupled to a control gate (6), a source electrode (10) coupled to a highly-doped source region (4), and a drain electrode (11) coupled to a lowly-doped drain region (8), wherein the vertical channel region (2) is on the semiconductor substrate (1) and has shape of cuboid; the gate dielectric layer (5) and the control gate (6) are on one side of the lower portion of the vertical channel region (2) and the highly-doped source region (4) is on the other three sides of the lower portion of the vertical channel region (2), the lowly-doped drain region (8) locates on the top of the vertical channel region (2), an isolation region (7) is provided between the lowly-doped drain region (8) and the control gate (6), the lowly-doped drain region (8) is doped with impurities having a doping type opposite to that of the highly-doped source (4), and the lowly-doped drain region (8) has a doping concentration between 5×10¹⁷ cm⁻³ and 1×10¹⁹ cm⁻³ and the highly-doped source region (4) has a doping concentration between 1×10¹⁹ cm⁻³ and 1×10²¹ cm⁻³. The semiconductor substrate (1) has a doping concentration between 1×10¹⁴ cm⁻³ and 1×10¹⁷ cm⁻³. The cuboid-shaped vertical channel region (2) has a length and a width equal to each other and less than a width of a source depletion layer which is in a range of 25 nm-1.5 μm, and has a height more than the length and the width thereof, where the ratio of the height of the vertical channel region (2) to the width thereof is 1.5:1-5:1. A vertical distance between the lowly-doped drain region (8) and the control gate (6) is 10 nm-1 μm.

A fabrication method of the tunneling field effect transistor described above comprises the steps of:

(1) depositing a hard mask layer on a semiconductor substrate, defining a pattern for a vertical channel region by performing photoetching, and forming the vertical channel region by performing deep etching under the protection of a hard mask;

(2) forming a highly doped source region surrounding four sides of the vertical channel region by performing ion implantation under the protection of the hard mask; and performing photolithography to expose only the highly-doped source region on one of the four sides and performing etching with an etching depth greater than an ion implantation depth, so that only the highly-doped source region surrounding the other three sides remains;

(3) growing a gate dielectric layer and depositing a control gate material;

(4) then depositing an isolation layer material, performing etching back till polysilicon over the highly-doped source region, and wet-etching the polysilicon under the protection of the isolation layer, so that only the polysilicon layer covered with the isolation layer remains as a vertical control gate;

(5) further depositing an isolation layer with a deposited thickness which defines a length of a region between the gate and the drain and not covered with the gate; forming a lowly-doped drain region with the other doping type by performing ion implantation under the protection of the isolation layer, and then performing rapid high temperature thermal annealing to activate the doped impurities;

(6) finally forming the tunneling field effect transistor, as shown in FIG. 1 by proceeding to a general CMOS Back-End-Of-Line, comprising further depositing an isolation layer, opening contact holes and performing metallization.

In the fabrication method described above, a material for the semiconductor substrate in the step (1) is selected from a group consisting of Si, Ge, SiGe, GaAs, and the other binary or ternary compound semiconductor in II-VI, III-V and IV-IV groups, silicon on insulator (SOI) and germanium on insulator (GOI).

In the fabrication method described above, a material for the gate dielectric layer in the step (3) is selected from a group consisting of SiO₂, Si₃N₄, and high-K gate dielectric material.

In the fabrication method described above, a process for growing the gate dielectric layer in the step (3) is selected from a group consisting of general thermal oxidation, nitrogen-doped thermal oxidation, chemical vapor deposition and physical vapor deposition.

In the fabrication method described above, the control gate material in the step (3) is selected from a group consisting of doped polysilicon, metal cobalt, nickel and the other metal and metal silicide.

The present invention has the technical effects as follows:

Firstly, the PN junction provided by a highly-doped source region surrounding three sides of the vertical channel region of the tunneling field effect transistor of the present invention can deplete effectively the channel region, so that energy band of the surface channel under the gate is lifted, therefore the device may obtain a steeper energy band and a narrower tunneling barrier width than the conventional TFET when the band-to-band tunneling occurs, equivalently achieving the effect of a steep doping concentration gradient at the tunneling junction, and thereby the sub-threshold characteristics are significantly improved relative to the conventional TFET. At the same time, compared with a junction-depletion-mode tunneling field effect transistor with a planar strip-shaped gate, the three sides-surrounding structure of the present invention can modulate more effectively the tunneling junction to obtain the steeper sub-threshold characteristics, because depletion is caused by only the PN junctions on the two sides with respect to a planar structure.

Secondly, on the premise of not increasing the area of the active region, the design of the vertical channel region of the present invention can improve effectively the tunneling area which is determined by the area of the interface between the highly-doped source region and gate, as shown by the section outlined by a dashed box in FIG. 1a. The increase in the tunneling area can be benefit to further improve the on-state current of the device.

Thirdly, the present invention adopts a short gate design, that is, the gate electrode covers a part of the channel region so that there is an uncovered region of a certain distance between the gate and the drain. The design not only can inhibit effectively the tunneling at the drain junction, that is, the ambipolar effect in the conventional TFET, but also can reduce the influence of the gate electrode on the uncovered region and accordingly can inhibit the tunneling of the parasitic tunneling junction in a small size device, the place where the parasitic tunneling junction occurs is the location indicated by a point B in FIG. 1a. Therefore, the sub-threshold slope of the device may be decreased when the device is turned on. In addition, the lower doping concentration of the drain region may also further inhibit the ambipolar effect.

Fourthly, the fabrication process of the device is simple, and the fabrication method is fully compatible with the conventional MOSFET process.

In short, the tunneling area of the device is increased due to application of the vertical channel region to the device structure, the application of the design of the highly-doped source region surrounding the channel region on three sides modulates effectively the tunneling junction at the source, and inhibits the ambipolar effect and the tunneling of the parasitic tunneling junction in the small size device, improving the on-state current and the sub-threshold characteristics of TFET device, and the fabricating method is simple. Compared with the existing TFET, in the case of the same active region size, the device of the present invention can obtain a higher turn-on current and a steeper sub-threshold slope, and can maintain a lower leakage current, and thus the device can be expected to be applied in the field of the low power consumption, and has a higher practical value.

### BRIEF DESCRIPTION OF THE DRAWINGS

FIG. 1 a is a cross-section schematic view illustrating a junction-modulated vertical tunneling field effect transistor according to the present invention, FIG. 1b is a top view of the device taken along AA′ direction of FIG. 1a, wherein the arrow direction indicates the tunneling direction;

FIG. 2a is a cross-section view of the device after a vertical channel is formed by performing etching and then a highly-doped drain region is formed by ion implantation under the protection of a hard mask, FIG. 2b is a corresponding top view of the device;

FIG. 3a is a cross-section view of the device after only one side of the vertical channel region is exposed after photolithography and then a trench is formed by performing etching, FIG. 3b is a corresponding top view of the device;

FIG. 4a is a cross-section view of the device after a gate dielectric layer is grown and then a control gate material is deposited, FIG. 4b is a corresponding top view of the device;

FIG. 5a is a cross-section view of the device after an isolation layer is deposited and then an etching back and a wet-etching are performed to remove the unprotected polysilicon, FIG. 5b is a corresponding top view of the device;

FIG. 6a is a cross-section view of the device after an isolation layer is further deposited and then a lowly-doped drain region with an opposite doping type is formed by ion implantation, FIG. 6b is a corresponding top view of the device;

FIG. 7 is a cross-section view of the junction-modulated vertical tunneling field effect transistor after an isolation layer is further deposited, contact holes are opened and then metal leadings are formed;

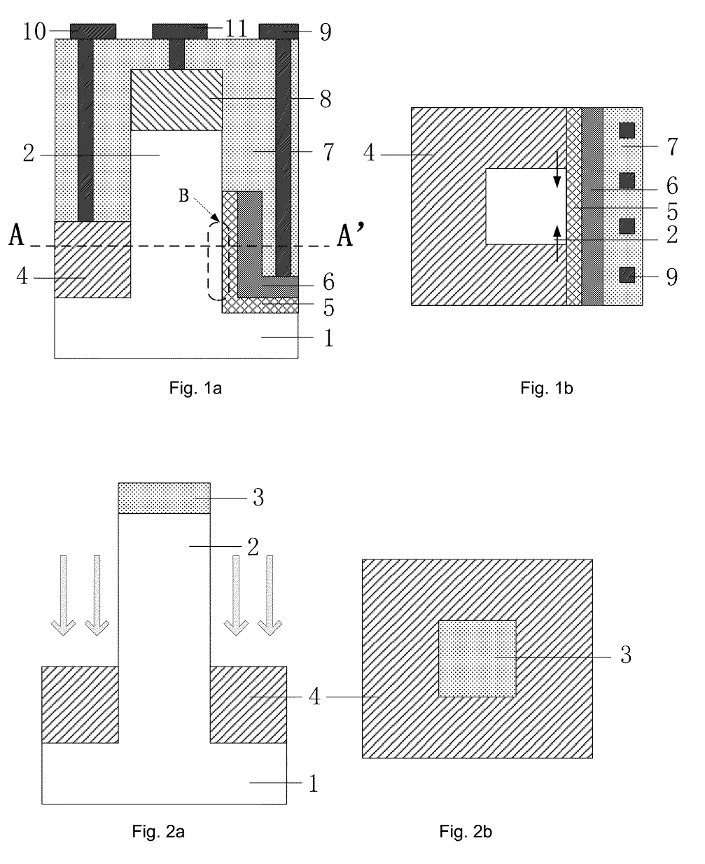

In the drawings:

| | |
|---|---|
| 1—a semiconductor substrate | 2—a vertical channel region |
| 3—a hard mask layer | 4—a highly-doped source region |
| 5—a gate dielectric layer | 6—a control gate |
| 7—an isolation layer | 8—a lowly-doped drain region |
| 9—a gate electrode | 10—a source electrode |
| 11—a drain electrode | |

### DETAILED DESCRIPTION OF THE EMBODIMENTS

Hereinafter, the present invention will be further described with respect to the examples. It is noted that, the embodiments are provided so that this disclosure will be thorough and complete, and will fully convey the scope of the present invention to those skilled in the art, and it will be appreciated to those skilled in the art that various changes and modifications may be made without departing from the spirit and scope defined by the present invention and the accompanying claims. Accordingly, the present invention should not be construed as being limited to the embodiments, and the protected scope of the present invention should be defined by the claims.

A specific example of the fabrication method according to the present invention includes the process steps shown in FIG. 2 to FIG. 7:

1. A hard mask layer 3 is deposited on a silicon substrate 1 in the form of a bulk silicon wafer with a crystal orientation (100), wherein the hard mask layer is Si₃N₄ and has a thickness of 300 nm, and the substrate has a lightly-doped doping concentration; then a square pattern for a vertical channel region 2, with a length and a width of 50 nm, is defined by performing photoetching; and the vertical channel region 2 is formed by deeply etching the silicon materials under the protection of a hard mask;

2. A highly-doped source region 4 is formed surrounding four sides of the vertical channel region by performing P+ ion implantation, with an ion implanting energy of 40 keV and an implanting impurity of BF²⁺, under the protection of the hard mask, as shown in FIG. 2a and FIG. 2b;

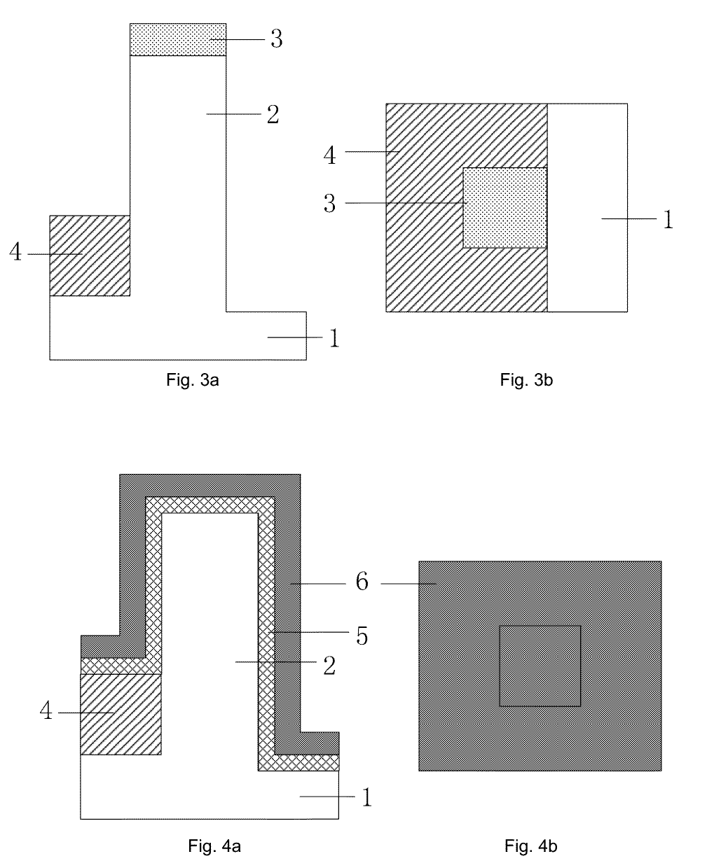

3. only the highly-doped source region around one of the four sides of the vertical channel region is exposed by photolithography and then the silicon is etched with an etching depth of 500 nm, so that only the highly-doped source region surrounding the other three of the four sides remains, and then a photoresist is removed, as shown in FIG. 3a and FIG. 3b;

4. A gate dielectric layer 5 is formed by thermal growing, wherein the gate dielectric layer is SiO₂ and has a thickness of 1-5 nm; and a gate material is deposited to form a doped polysilicon layer with a thickness of 150-300 nm, as shown in FIG. 4a and FIG. 4b;

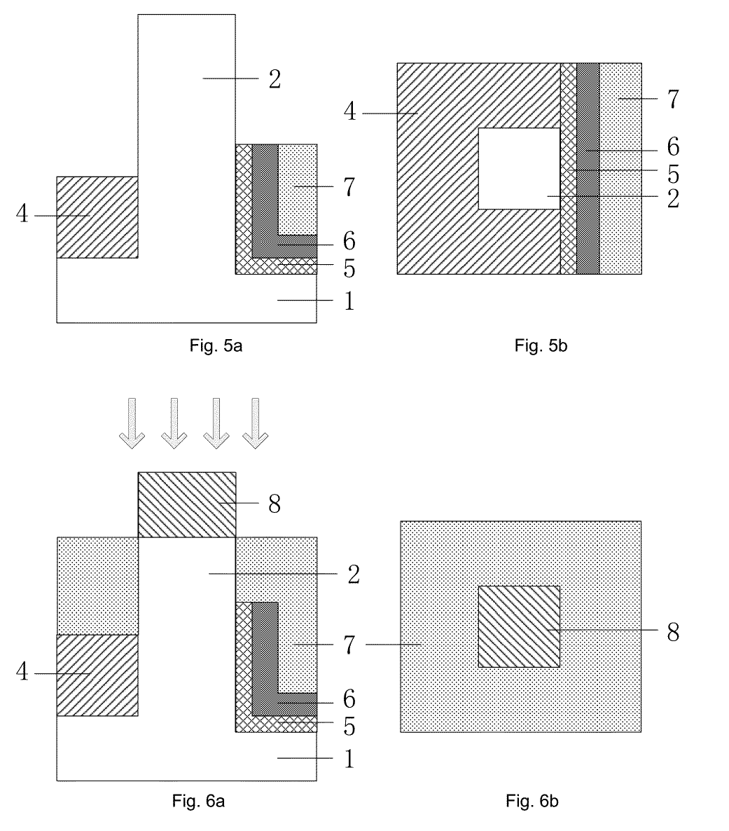

5. An isolation layer 7 is deposited, wherein the isolation layer is SiO₂ and has a thickness of 1 μm, and then an etching back is performed with the polysilicon on the highly-doped source region as a stopping layer; then under the protection of the isolation layer 7, only the polysilicon layer covered with the isolation layer remains as a vertical control gate 6 by isotropic etching the polysilicon layer, as shown in FIG. 5a and FIG. 5b;

6. A lowly-doped drain region 8 with the other doping type is formed by further depositing SiO₂ with a deposited thickness of 50 nm and then performing N ion implantation with ion implantation energy of 50 keV and implanting impurity of As⁺, as shown in FIG. 6a and FIG. 6b; and the source and drain doped impurities are activated by performing a rapid high temperature annealing;

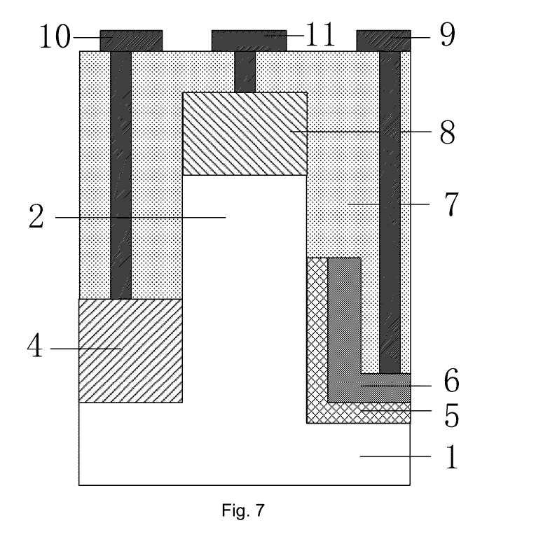

7. Finally by proceeding to a general CMOS Back-End-Of-Line, comprising depositing a passivation layer, opening contact holes, and performing metallization, the junction-modulated vertical tunneling field effect transistor may be formed, as shown in FIG. 7.

Although the present invention has been described with respect to the preferred embodiment as above, however, it is not intended to limit the present invention. Various changes and modifications for the present technical solution may be made or equivalent embodiments may be obtained by those skilled in the art in view of the method and technical contents disclosed above, without departing from the scope of the present invention. Therefore, any simple changes, equivalent changes and modifications made to the above embodiments according to the present invention technical spirit without departing from the spirit of the present invention all fall into the protection scope of the present invention.

What is claimed is:

1. A tunneling field effect transistor, comprising a semiconductor substrate (1), a vertical channel region (2), a highly-doped source region (4), a lowly-doped drain region (8), a gate dielectric layer (5), and a control gate (6), and a gate electrode (9) coupled to the control gate (6), a source electrode (10) coupled to the highly-doped source region (4), and a drain electrode (11) coupled to the lowly-doped drain region (8), wherein the vertical channel region (2) is on the semiconductor substrate (1) and has shape of cuboid; the gate dielectric layer (5) and the control gate (6) are on one side of the lower portion of the vertical channel region (2) and the highly-doped source region (4) is on the other three sides of the lower portion of the vertical channel region (2), the lowly-doped drain region (8) locates on the top of the vertical channel region (2), an isolation region (7) is provided between the lowly-doped drain region (8) and the control gate (6), the lowly-doped drain region (8) is doped with impurities having a doping type opposite to that of the highly-doped source (4), and the lowly-doped drain region (8) has a doping concentration between 5×10¹⁷ cm⁻³ and 1×10¹⁹ cm⁻³ and the highly-doped source region (4) has a doping concentration between 1×10¹⁹ cm⁻³ and 1×10²¹ cm⁻³.

2. The tunneling field effect transistor according to claim 1, wherein the semiconductor substrate (1) has a doping concentration between 1×10¹⁴ cm⁻³ and 1×10¹⁷ cm⁻³.

3. The tunneling field effect transistor according to claim 1, wherein the vertical channel region (2) has a length and a width equal to each other and less than a width of a source depletion layer which is in a range of 25 nm-1.5 μm, and has a height more than the length and the width thereof, where ratio of the height of the vertical channel region (2) to the width thereof is 1.5:1-5:1.

4. The tunneling field effect transistor according to claim 1, wherein a vertical distance between the lowly-doped drain region (8) and the control gate (6) is 10 nm-1 μm.

5. A fabrication method of the tunneling field effect transistor according to claim 1, comprising the steps of:
1) depositing a hard mask layer on a semiconductor substrate, defining a pattern for a vertical channel region by performing photoetching, and forming the vertical channel region by performing deep etching under the protection of a hard mask;
2) forming a highly-doped source region surrounding the vertical channel region on four sides thereof by performing ion implantation under the protection of the hard mask, and performing photolithography to expose only the surrounding highly-doped source region on one of said four sides and performing etching with an etching depth greater than an ion implantation depth, so that only the surrounding highly-doped source region on the other three sides remains;
3) growing a gate dielectric layer, and depositing a gate material;
4) depositing an isolation layer material, performing etching back till polysilicon on the highly-doped source, and wet-etching the polysilicon under the protection of the isolation layer, so that only the polysilicon layer covered with the isolation layer remains as a vertical control gate;
5) further depositing an isolation layer with a deposited thickness which defines a length of a region between the drain and the gate and not covered with the gate; forming a lowly-doped drain region with the other doping type by performing ion implantation under the protection of the isolation layer, and then performing a rapid thermal annealing to activate the doped impurities;
6) finally forming the tunneling field effect transistor according to the claim 1 by proceeding to a CMOS Back-End-Of-Line, comprising further depositing an isolation layer, opening contact holes, and performing metallization.

6. The fabrication method according to claim 5, wherein a material for the semiconductor substrate in the step 1) is selected from a group consisting of Si, Ge, SiGe, GaAs and other binary or ternary compound semiconductor in II-VI, III-V and IV-VI groups, silicon on insulator and germanium on insulator.

7. The fabrication method according to claim 5, wherein a material for the gate dielectric layer in the step 3) is selected from a group consisting of SiO₂, Si₃N₄, and high-K gate dielectric material.

8. The fabrication method according to claim 5, wherein a process for growing the gate dielectric layer in the step 3) is selected from a group consisting of thermal oxidation, nitrogen-doped thermal oxidation, chemical vapor deposition and physical vapor deposition.

9. The fabrication method according to claim 5, wherein the control gate material in the step 3) is selected from a group consisting of doped polysilicon, metal cobalt, or nickel.
